(19) United States
(12) Patent Application Publication
(10) Pub. No.: US 2008/0083611 A1
(43) Pub. Date: Apr. 10, 2008

(54) High-adhesive backside metallization

(75) Inventor: Valery Felmetsger, Goleta, CA (US)

Correspondence Address: TUE NGUYEN, 496 OLIVE AVE, FREMONT, CA, 94539, US

(73) Assignee: TEGAL CORPORATION, Petaluma, CA (US)

(21) Appl. No.: 11/863,046

(22) Filed: Sep. 27, 2007

Related U.S. Application Data
(60) Provisional application No. 60/849,996, filed on Oct. 6, 2006.

(51) Int. Cl. C23C 14/35

(52) U.S. Cl. 204/192.15; 204/192.11

(57) ABSTRACT

High-adhesive backside metallization may be realized when Ti is deposited with relatively low rf substrate bias power without pre-deposition rf plasma etch of the wafer. Rf induced bias voltage in the range of −50 V to −250 V ensured the best adhesion property of the film stack. Analysis of the interface between Ti layer and Si substrate have shown that Si diffused into Ti layer on a distance up to a depth of 10 nm, while Ti atoms penetrated about 2 nm into the Si. Hence Ti deposition with rf substrate bias enhances intermixing between Ti and Si atoms by low-energy ion bombardment without accumulation of Ar atoms in the interface area as it is inherent to metallization with pre-deposition rf plasma etch.

### Background

In recent years, magnetron sputtering PVD has become the technology of choice in mass production of discrete and power devices such as metal-oxide-semiconductor field effect transistors (MOSFET) and insulated gate bipolar transistors (IGBT). In order to realize enhanced performance, advanced power devices require using thin (below 200 μm) and even ultra thin (down to 50 μm) wafers. Because the wafer's backside is an active part of the majority of modern power devices, innovations in the wafer backside processing technology enable further device improvement.

A typical backside metal stack for power device fabrication usually consists of three layers: Ti (20-200 nm)/NiV alloy or pure Ni (200-400 nm)/Ag (100-2000 nm). Ti is an adhesion layer, NiV or Ni is a solderable layer and a diffusion barrier between Si and solder, and Ag ensures the best solder wetability and prevents the Ni layer from oxidation prior to the soldering process. In some applications, an additional metal film such as Al (50-100 nm thick) may be deposited before deposition of the Ag/NiV/Ti film stack to create a doped Si layer (for instance, n⁺ layer).

Besides gentle and accurate handling in a sputter tool, backside deposition process requires effective stress control of the film stack to reduce additional warp of the wafer, especially its “potato chipping”, which usually occurs if stress has non-uniform distribution across the wafer. Low Ohmic contact resistance and superior film adhesion are the most important requirements for backside metallization process.

Ti under-layer is widely used in backside metallization technology as a material ensuring high adhesion to Si substrate. However, adhesion strength may be essentially different, depending on the wafer surface condition, pre-deposition wafer treatment technology, and parameters of the film deposition process.

It is well-known that heating the wafer before and during deposition of the first layer allows enhancing the film adhesion and improving Ohmic contact formation due to stimulation of diffusion between film and substrate material. Deposition at elevated temperature is not desirable for ultra thin wafers because efficiency of stress control depends on the wafer temperature. Low temperature processing enables lower tensile or more compressive stress in the metal films. It is necessary also to point out that some device manufacturers prefer to use wafer supporting polymer tapes to reduce thin wafer breakage after its grinding. These tapes usually cannot resist temperature above 180-200 C.

Surface pre-treatment by means of Ar ion beam bombardment and etching in rf plasma have been well-known methods to enhance the film adhesion by removing native oxide and residual contamination from the surface, and by activating chemical bonds on the surface. Nevertheless, ion bombardment is not always useful method to improve the film adhesion. It has been found that two amorphous layers appeared at the interface between magnetron sputtered Ti film and Si substrate. One layer close to the Ti film was an amorphous Ti—Si mixed layer created by inter-diffusion mechanism and the other was amorphous silicon saturated with Ar atoms as a result of an energetic Ar ion bombardment. High concentration of argon at the interface leads to deterioration of adhesion between the amorphous silicon and Ti—Si layer. Even in the case of surface treatment with relatively low energy Ar ions (50V), the adhesion of the Ti films was lower than the adhesion of the films deposited on the chemically etched Si substrate.

### SUMMARY

The present invention discloses methods and apparatuses for high adhesive backside metallization between a metal layer and a substrate. In one embodiment, the high adhesion can be achieved by the enhancement of the intermixing between the metal and the substrate atoms. In one aspect, the intermixing enhancement includes low energy ion bombardment. In other aspect, the intermixing enhancement includes the elimination of Ar atoms in the interface area, typically resulted from Ar rf plasma pre-clean or pre-deposition etch. The substrate is preferably silicon and the metal layer is preferably Ti, but other substrates such as silicon-containing substrates, doped silicon substrates, Galas substrates, glass substrate and other metals such as Al, Ni, V, Ag or any combinations thereof can also be used.

In one embodiment, the present invention discloses a low energy ion bombardment of the substrate. In one aspect, the low energy ion bombardment is measured through low substrate rf bias voltage. The rf substrate bias voltage is preferably between −10V to −450V, more preferably between−20V to −300V, and most preferably between −50V to −250V. In other aspect, the low energy ion bombardment is measured through low substrate rf bias power. The rf substrate bias power is preferably between 50 W to 300 W. There is a relationship between substrate rf power and voltage, depending on the system configurations and process conditions.

In other embodiment, the present invention discloses a low energy ion bombardment of the substrate only at the beginning of the deposition of the metal layer. The improvement of the adhesion strength occurs mostly at the metal/substrate interface, and thus the proper process conditions at the beginning of the deposition of the metal layer are critical. In other embodiment, the low energy ion bombardment conditions occur throughout the deposition of the metal layer.

In other embodiment, the present invention discloses an adhesion improvement through interface preparation. In one aspect, the interface preparation involves the reduction in impurity at the interface area to improve the adhesion strength. The impurity species is typically sputter atom Ar. In other aspect, the interface preparation involves the elimination of the sputtered clean, the pre-deposition clean, or the pre-deposition etch. The elimination of the exposure of the substrate to energetic Ar atoms provides the improvement in the adhesion of the subsequent metal layer deposition, probably due to the reduction of Ar impurity at the interface of the substrate and the metal layer. In other aspect, the interface preparation involves low power surface pre-treatment such as Ar ion beam bombardment in sputtered clean, the pre-deposition clean, or the pre-deposition etch. The pre-clean step provides the removal of gross imperfection at the substrate, and the low power provides the minimal, or negligible, damage to the interface. In one aspect, low energy surface pre-treatment according to the present invention involves Ar ion energy lower than 50V.

In one embodiment, the thickness of the metal layer is designed to withstand the stress of the subsequent metallization layers, such as Ni, NiV, or Ag. In one aspect, the thickness of the metal layer preferably provides adequate mechanical strength to resist delamination due to the subsequent additional stress. In other aspect, the thickness of the metal layer is higher than 20 nm, and preferably higher than 50 nm.

In other embodiment, the present invention discloses a process for improving adhesion strength, involving low substrate bias during the initial deposition of Ti or Al on a silicon substrate. The process is typical backside metallization process, including metallization stack of Ti/Ni/Ag, Ti/NiV/Ag, Al/Ti/Ni/Ag, or Al/Ti/NiV/Ag. In one aspect, the process involves low temperature deposition with improved adhesion strength. In other aspect, the process involves low deposition rate with improved adhesion strength.

In other embodiment, the present invention discloses an apparatus for improving adhesion strength, involving low substrate bias during the initial deposition of Ti or Al on a silicon substrate. In one aspect, the apparatus includes an S-gun magnetron. The S-gun magnetron can include a plurality of conical targets, independently or dependently powered. In other aspect, the apparatus includes additional rf power to apply to a substrate's support, which can generate substrate bias. The rf frequency is preferably 13.56 MHz, but other frequencies can be used.

### BRIEF DESCRIPTION OF THE DRAWING

FIG. 1 shows a schematic diagram of the process module with S-Gun magnetron.

FIG. 2 shows the variation of stress in Ti films vs. rf bias power.

FIG. 3A illustrates an HR-TEM cross-sectional micrograph of the sample deposited without rf bias in Ti sputter recipe, showing localized strain fields in the Si right under Ti film.

FIG. 3B illustrates an HR-TEM cross-sectional micrograph of the sample deposited without rf bias in Ti sputter recipe, showing an interfacial amorphous Si—Ti mixed layer appeared as a result of Si diffusion into Ti film.

FIG. 4A illustrates an HR-TEM cross-sectional micrograph of the sample deposited with rf bias power (50 W) in Ti sputter recipe, showing numerous strain fields in the Si.

FIG. 4B illustrates an HR-TEM cross-sectional micrograph of the sample deposited with rf bias power (50 W) in Ti sputter recipe, showing thin light-contrasted layer in the substrate near interface is Si enriched with Ti atoms due to effects of recoil implantation and ion-stimulated diffusion of Ti atoms into the substrate.

Table I. Adhesion of Ag/Ni/Ti film stack vs. pre-deposition wafer treatment and bias in Ti sputter recipe.

Table II. XEDS analysis data (no bias sample).

Table III. XEDS analysis data (bias sample).

### DETAILED DESCRIPTION OF THE EMBODIMENTS

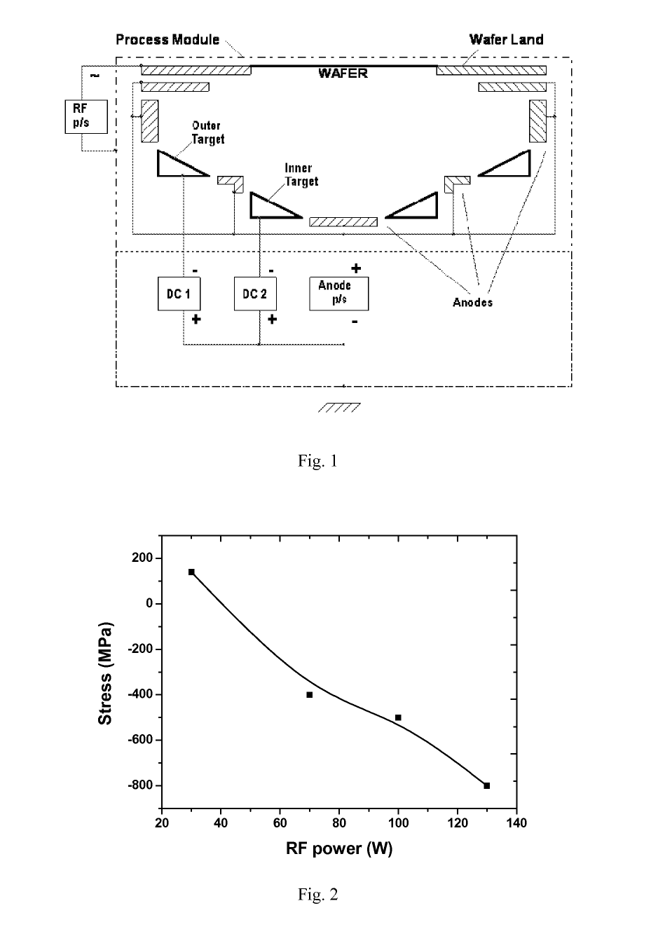

Samples for adhesion tests were deposited with a film stack of Ag (600 nm)/Ni (300 nm)/Ti (100 nm) in an Endeavor-AT cluster tool equipped with S-Gun dc magnetrons. The S-Gun magnetron has two independently powered conical targets, mounted concentrically, with a bias-able central anode (FIG. 1). Additional rf power may be applied to a wafer land (13.56 MHz) igniting rf plasma discharge in the wafer vicinity, which generates a negative self-bias on the substrate. This creates low energy ion bombardment during film growth. The S-Gun sputters up, so the substrate is placed face down on the wafer land. No clamps or clips are required to keep the wafer in place during deposition. This handling feature enables gentle wafer handling and film sputtering without any deleterious effects on the front side device structures. The base pressure in the process modules pumped by turbo and cryo pumps was 6.6×10⁻⁶ Pa.

Deposition rates were relatively low (150, 180, and 490 nm/min for Ti, Ni, and Ag, respectively) enabling better stress control in the film stack on ultra thin wafers. The deposition for Ti is preferably between 50 to 300 nm/min. The deposition for Ni is preferably between 300 to 800 nm/min. And the deposition for Ag is preferably between 50 to 300 nm/min. Ti films were sputtered with rf substrate bias power varied in the range of 0-300 W. During deposition without rf power, the wafers had positive (few volts) self-bias. Value of the rf induced negative potential on the wafer disproportionately increased with rf power, reaching −430 V at 300 W.

In experiments with pre-deposition wafer etch, capacitively coupled planar rf plasma etch source was employed. Etch rate can be varied in the range of 10-50 nm/min by applied rf power.

For estimation of adhesion two methods are employed: a simple scratch and sticky tape test (on regular thick wafers) and a solder bend test (on thinned wafers). The solder bend test actually imitates soldering of the dies to the packaging base. For this test, we cut the wafer into the small pieces (dies) and solder them onto Ni pods covered by Pb—Sn alloy. After bending (twisting) the pods to break Si completely, the surface is evaluated by optical microscope. If the whole surface is covered by crunchy silicon, the adhesion is 100%. If all Si is removed from the surface during this test, the adhesion has zero value.

The experiments used 150-mm Si wafers (B doped p-type and As doped n-type) with power MOSFET dies on the front side. The back surface of the wafers received spin wet etching following by grinding. Surface finishing was mirror or rough. Wafer thickness was 95 and 65 μm. Because adhesion is usually weaker on mirror surface compared to rough surface, for scratch and tape adhesion tests, we also deposited film stack onto polished (mirror) side of regular thick Si wafers in order to verify adhesion in the worst conditions.

The film stack had poor adhesion when Ti was deposited without rf bias. Scratch and tape test showed film peeling on entire wafer surface. Is was found that Ti deposited with relatively low bias voltage in the range of −50 V to −250 V provides the best adhesion property of the film stack (see Table I). Adhesion strength of 100 nm thick Ti film was excellent even if rf bias power was applied only at the beginning of the Ti sputter process (during growth of the first 20 nm film). However deposition with high bias voltage led to adhesion degradation. Peeling, an indication of adhesion degradation, was observed on the wafer edge when Ti film was deposited with bias voltage −300 V and −430 V. Infringement of the film stack adhesion in this case might occur due to developing high compressive stress in the Ti with increasing bias (FIG. 2).

Pre-deposition rf plasma etch influenced negatively the film stack adhesion. In etch recipes rf power is varied in the wide range from 50 to 500 W, producing a self-bias voltage on the wafer from −100 to −1200 V. In all experiments, adhesion was essentially lower on the samples deposited with etch comparing with the samples deposited without etch. Even when Ti film was deposited with optimal bias −170 V, Si remaining after solder bend test was just 70% compared to 100% Si remaining in the case of no etch applied.

The adhesion of the backside stack can depend on the Ti film thickness. Scratch and tape test has shown that adhesion of the stack with 20 nm thick Ti was non-uniform across the wafer. There was no film peeling observed in the wafer center but delamination was found on the wafer edge areas, while metallization with Ti thicker than 50 nm had no peeling on the entire wafer surface. Solder bend test confirmed that 50-100 nm thick film ensures superior adhesion.

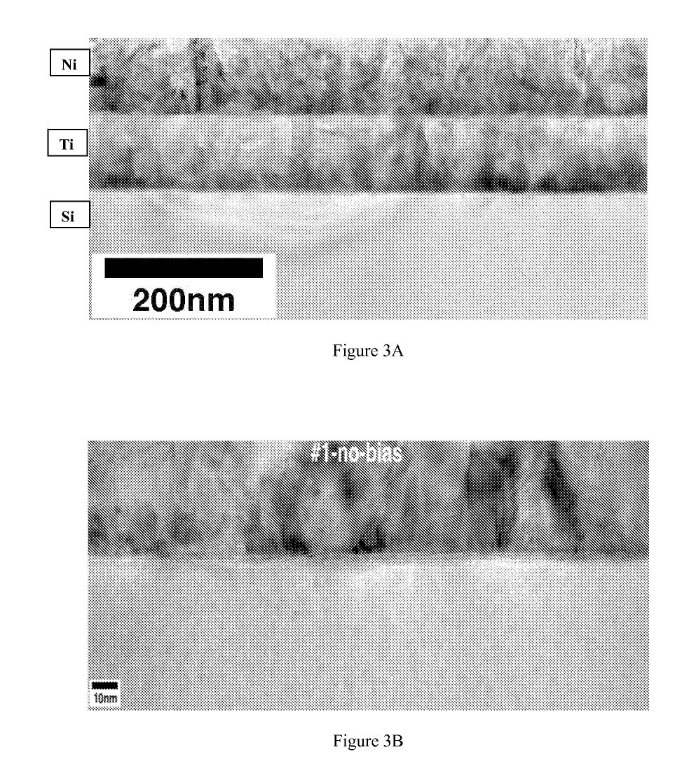

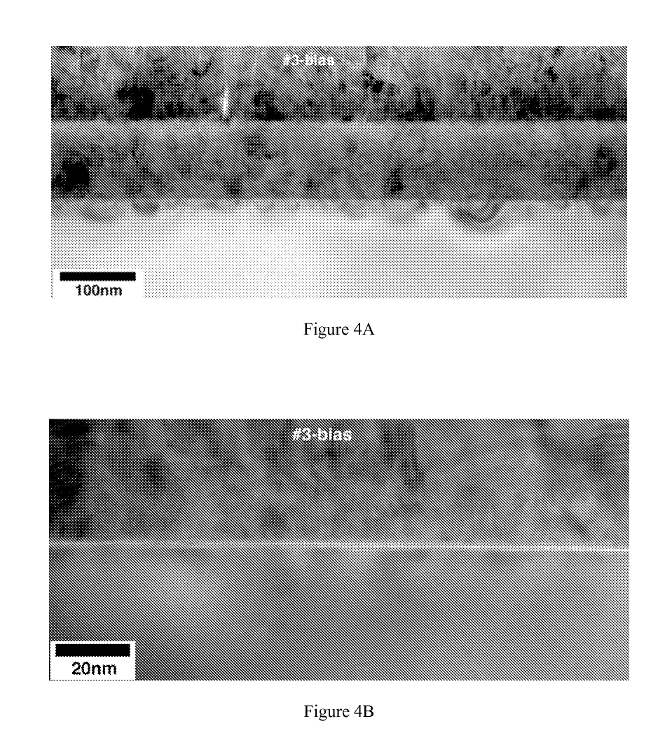

In order to better understand a mechanism of adhesion enhancement as a result of Ti deposition with rf bias, analytical measurements are performed, such as a high-resolution transmission electron microscopy (HR-TEM) investigation with a quantitative X-ray energy disperse spectroscopy (XEDS) compositional analysis of the interface between Ti layer and Si substrate. Cross-section micrographs by HR-TEM are presented in FIGS. 3 and 4. XEDS analyses were completed in 4 points located 55 nm above the Ti—Si interface in the Ti layer (site 1), on the interface (site 2), about 5 nm below the interface (site 3), and 100 nm below the interface in the Si substrate (site 4).

XEDS data presented in Tables II and III indicated that Si diffused deeply into the Ti film. Si concentration was high enough even on distance 55 nm from the interface in both samples (about 6 at. %). There are also numerous localized strain fields in the Si right under Ti film, probably due to the residual stress at the Si—Ti interface.

HR-TEM revealed an interfacial layer between the Ti and Si in the sample deposited without bias in Ti sputter recipe (FIG. 3). This layer is located below the interface to a depth of about 3-4 nm. XEDS data (Table II) show that layer consists of mostly Si (95-97 at. %) with some incorporation of Ti atoms (5-3 at. %). This layer might be interpreted as an amorphous Si—Ti mixed layer.

In the sample deposited with rf bias power 50 W, a thin light-contrasted layer about 1-1.5 nm thick was detected in the substrate near interface (FIG. 4). An atomic concentration of Ti in the site 2 (Table III) exceeded about 10 times its concentration measured in the no-bias sample in the same location. Consequently, this layer might be identified as outcome of Ti penetration into the Si.

Thickness of the amorphous Ti—Si mixed layer was about 3 nm when Ti film was deposited by planar magnetron without substrate bias. This layer appeared due to diffusion of Si atoms into the growing Ti film. An important feature of the interface when Ti film is deposited by S-Gun magnetron with substrate bias is the formation of essentially extended modified layer between Si substrate and Ti film. HR-TEM and XEDS investigation elicited that Si diffused into Ti layer to a depth of 10 nm, while Ti atoms penetrated about 2 nm into the Si. Thus inter-diffused Ti—Si layer has thickness of about 12 nm and consists of two sub-layers. One of them is Si enriched with Ti atoms due to effects of recoil implantation and ion-stimulated diffusion of Ti atoms into the substrate. Another one is Ti enriched with diffused Si atoms.

Ti deposition with substrate bias enhances intermixing between Ti and Si atoms by low-energy ion bombardment without accumulation of Ar atoms in the interface area as observed on the wafer processed with pre-deposition rf plasma etch. As a result, an extended modified Ti—Si layer is formed on the substrate, ensuring better bonding with Ti film and thus improving the adhesion strength of the film stack.

The weakening of adhesion (strength failure) that we found inherent to relatively thin Ti films may be explained on bi-layer structures of Ti and Ni deposited on Si substrate. Internal stress in Ni film was found to induce an additional stress, which concentrates at the interface between the Si substrate and the Ti film. Adhesion failure appears because mechanical strength of thin Ti is not enough to resist a peel-off force produced by inducted stress. Therefore, for reliable adhesion of the Ag/Ni/Ti backside metallization to the Si substrate, the Ti film thickness should be at least 50 nm or higher.

The present invention discloses the critical features of backside metallization of ultra thin wafers, particularly technological solutions for high film adhesion and low contact resistance without wafer heating or post-deposition sintering. The adhesion of Ag/Ni/Ti film stack deposited by e.g. S-Gun dc magnetrons depends on sputtering conditions of the Ti under layer. High-adhesive backside metallization may be realized when Ti is deposited with relatively low rf substrate bias power without pre-deposition rf plasma etch of the wafer. Rf induced bias voltage in the range of −50 V to −250 V ensured the best adhesion property of the film stack. HR-TEM with XEDS investigation of the interface between Ti layer and Si substrate have shown that Si diffused into Ti layer on a distance up to a depth of 10 nm, while Ti atoms penetrated about 2 nm into the Si. Hence Ti deposition with rf substrate bias enhances intermixing between Ti and Si atoms by low-energy ion bombardment without accumulation of Ar atoms in the interface area as it is inherent to metallization with pre-deposition rf plasma etch. As a result, an extended modified layer is formed on the substrate, ensuring better bonding with Ti film, thus improving the adhesion strength of the film stack.

What is claimed is:

1. A method for improve adhesion between a substrate and a deposited metal thin film, comprising:
depositing the thin film using metal ion bombardment at a temperature below 200° C.,
wherein the energy of the metal ion is sufficiently high to achieve an interface mixing between the metal and the substrate atoms, and
wherein the energy of the metal ion is sufficiently low to prevent stress damage to the substrate.

2. A method as in claim 1 wherein metal ion bombardment is achieved by applying bias to the substrate between −50V and −250V.

3. A method as in claim 1 wherein metal ion bombardment is achieved by applying power between 25 W to 300 W to the substrate, which generates self bias.

4. A method as in claim 1 wherein stress damage control comprises stress less than 1000 MPa.

5. A method as in claim 1 wherein the temperature is chosen to prevent stress damage control to the substrate.

6. A method as in claim 1 further comprising no surface treatment with plasma rf before depositing the thin film.

7. A method as in claim 1 wherein the thickness of the deposited thin film is between 50 to 100 nm.

8. A method for improve adhesion between a substrate and a deposited metal thin film, comprising:
depositing the thin film using metal ion bombardment at a temperature below 200° C., bias voltage between −50V to −250V, and without any plasma rf pre-treatment.

9. A method as in claim 8 wherein the bias voltage is achieved by applying power to the substrate, which generates self bias.

10. A method as in claim 8 wherein the bias voltage is chosen to minimizing stress damage to the substrate.

11. A method as in claim 8 further comprising no surface treatment with plasma rf before depositing the thin film.

12. A method for improve adhesion between a silicon-containing substrate and a deposited thin film of Ti, comprising:
depositing the Ti thin film using Ti ion bombardment at a temperature below 200° C., bias power between 50 W to 300 W, and without any plasma rf pre-treatment,
wherein the deposition uses a rf power for providing bias power to the substrate.

13. A method as in claim 12 wherein the deposition uses a S-Gun magnetron having powered conical targets.

14. A method as in claim 12 wherein the bias power generates a self bias voltage between −50V and −250V.

15. A method as in claim 12 wherein the bias power is chosen to minimizing stress damage to the substrate.

16. A method as in claim 12 wherein the temperature is chosen to minimizing stress damage to the substrate.

17. A method as in claim 12 further comprising no surface treatment with plasma rf before depositing the thin film.

18. A method as in claim 12 wherein depositing the Ti thin film comprising using bias power only at the interface of the thin film and substrate.

19. A method as in claim 12 wherein depositing the Ti thin film comprising using bias power throughout the whole deposition of the Ti thin film.

20. A method as in claim 12 further comprising depositing a multilayer of V and Ag on the Ti film.
